(19) United States
(12) Patent Application Publication
(10) Pub. No.: US 2023/0170920 A1
(43) Pub. Date: Jun. 1, 2023

(54) ENCODER CIRCUIT, DECODER CIRCUIT, ENCODING METHOD, AND DECODING METHOD FOR MULTILEVEL CODING

(71) Applicant: Fujitsu Limited, Kawasaki-shi (JP)

(72) Inventor: Yohei Koganei, Kawasaki (JP)

(73) Assignee: Fujitsu Limited, Kawasaki-shi (JP)

(21) Appl. No.: 17/983,431

(22) Filed: Nov. 9, 2022

(30) Foreign Application Priority Data
Nov. 29, 2021 (JP) 2021-192631

(51) Int. Cl. H03M 13/11; H04L 27/36

(52) U.S. Cl. CPC H03M 13/11; H04L 27/36

(57) ABSTRACT

Encoder circuit encodes information bits using 2^{2N} signal points. The encoder circuit includes: symbol mapper that allocates each symbol of frame including information bits, first code and second code to a corresponding signal point among 2^{2N} signal points according to mapping pattern; converter that converts information bits in other bit strings among N bit strings forming the frame excluding MSB string by using probabilistic shaping; first encoder that generates the first code from information bits in MSB string and the information bits converted by the converter; and second encoder that generates the second code from the information bits in MSB string and the first code. In the mapping pattern, values of bits corresponding to the other bit strings are arranged symmetrically in the constellation, and each pair of adjacent signal points on the constellation are different from each other in terms of value of bit corresponding to MSB string.

### CROSS-REFERENCE TO RELATED APPLICATION

This application is based upon and claims the benefit of priority of the prior Japanese Patent Application No. 2021-192631, filed on Nov. 29, 2021, the entire contents of which are incorporated herein by reference.

### FIELD

The embodiments discussed herein are related to an encoder circuit, a decoder circuit, an encoding method, and a decoding method for multilevel coding.

### BACKGROUND

Techniques for increasing the capacities of optical transmission systems have been required with an increase in the amount of information transmitted over networks. A multilevel modulation scheme has been put into practical use as one of the techniques for increasing the capacities of optical transmission systems. In the multilevel modulation scheme, a plurality of bits are carried by one symbol. For example, each symbol may carry four bits in 16 quadrature amplitude modulation (16 QAM), each symbol may carry six bits in 64 QAM, and each symbol may carry eight bits in 256 QAM.

If the number of bits carried by each symbol is excessively large, errors tend to occur because the Euclidean distances between signal points on a constellation are short. Thus, optical transmissions in the multilevel modulation scheme use error correction codes in many cases.

Error correction codes are classified into hard decision codes and soft decision codes according to a decoding method implemented by a receiver. Hard decision codes have a low error correction capability, but exhibit a good error floor and have low power consumption. Meanwhile, soft decision codes have a high error correction capability, but exhibit a bad error floor and have high power consumption. Thus, configurations in which hard decision codes and soft decision codes are combined have been proposed to attain both a high error correction capability and low power consumption. For example, a configuration is known in which soft decision codes are used as inner codes, and hard decision codes are used as outer codes.

A configuration is also known in which soft decision codes and multilevel coding (MLC) are combined. In this configuration, a soft decision decoding process can be omitted for some bits of a multilevel modulated signal, thereby decreasing power consumption of optical transmission devices. In addition, some bits are decoded first, and the result of decoding is used to decode remaining bits, so that errors can be suppressed, resulting in a little reduction in the error correction capability.

Meanwhile, Probabilistic Shaping (PS) is known as one technique for enhancing noise tolerance of transmission signals. In probabilistic shaping, transmission data is converted such that a transmitter uses a signal point close to the center of a constellation with a high probability. In this way, the average power of optical signals is decreased. In other words, if optical signals are transmitted with a specified average power, the Euclidean distances between signal points on the constellation increase. As a result, the noise tolerance of transmission signals is enhanced.

Configurations using probabilistic shaping in optical transmission systems for transmitting multilevel modulated signals are described in, for example, Japanese Laid-open Patent Publication No. 2020-188357 and Japanese Laid-open Patent Publication No. 2021-111864. Relevant techniques are described in Japanese Laid-open Patent Publication No. 2021-044681 and U.S. Patent Publication No. 2020/0177307.

As described above, multilevel coding can reduce power consumption of optical transmission devices while suppressing a reduction in an error correction capability. Probabilistic shaping can enhance the noise tolerance of transmission signals.

However, if multilevel coding and probabilistic shaping are combined according to the prior art, sufficient effects may not be provided. For example, the effect of multilevel coding or the effect of probabilistic shaping may be small. That is, the effect provided by multilevel coding and the effect provided by probabilistic shaping may not be both sufficiently provided.

### SUMMARY

According to an aspect of the embodiments, an encoder circuit encodes information bits in a transmission system that transmits symbols by using 2^{2N} signal points on a constellation. N is an integer larger than 2. The encoder circuit includes: a symbol mapper configured to allocate each symbol of a data frame including information bits, a first code and a second code to a corresponding signal point among the 2^{2N} signal points according to a mapping pattern; a converter configured to convert information bits stored in other bit strings among N bit strings forming the data frame excluding a first bit string among the N bit strings, such that a probability that each symbol is allocated to a signal point close to a center of the constellation is high; a first encoder configured to generate the first code from information bits stored in the first bit string and the information bits converted by the converter; and a second encoder configured to generate the second code from the information bits stored in the first bit string and the first code. The first code and the second code are stored in the first bit string. The mapping pattern indicates a correspondence between a signal point and values of N bits corresponding to the N bit strings. In the mapping pattern, values of bits corresponding to the other bit strings are arranged symmetrically with respect to the center of the constellation. In the mapping pattern, each pair of adjacent signal points on the constellation are different from each other in terms of a value of bit corresponding to the first bit string.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 illustrates an example of an optical transmission system in accordance with embodiments of the present invention;

FIG. 2 illustrates an example of an optical transceiver in accordance with embodiments of the present invention;

FIG. 3 illustrates an example of symbol mapping according to 64 QAM;

FIGS. 4A-4C illustrate an example of the configuration and operations of an encoder circuit in accordance with embodiments of the present invention;

FIG. 5 is an explanatory diagram for an overview of probabilistic shaping;

FIGS. 6A and 6B illustrate an example of probabilistic shaping;

FIGS. 7A and 7B illustrate an example of the configuration and operations of a decoder circuit in accordance with embodiments of the present invention;

FIGS. 8A-8C illustrate an example of a decoding process performed by a multi-stage decoder;

FIG. 9A-9C are explanatory diagrams for effects provided according to mapping patterns;

FIG. 10A and 10B are explanatory diagrams for problems according to other mapping patterns;

FIG. 11 is an explanatory diagram for reduction of power consumption;

FIGS. 12A-12C illustrate an example of the configuration and operations of an encoder circuit applied to 256 QAM;

FIG. 13 illustrates an example of the configuration and operations of a decoder circuit applied to 256 QAM;

FIGS. 14A and 14B illustrate variations of an encoder circuit and a decoder circuit applied to 16 QAM; and

FIGS. 15A and 15B illustrate an example of a data frame and a mapping pattern used in the variations depicted in FIGS. 14A and 14B.

### DESCRIPTION OF EMBODIMENTS

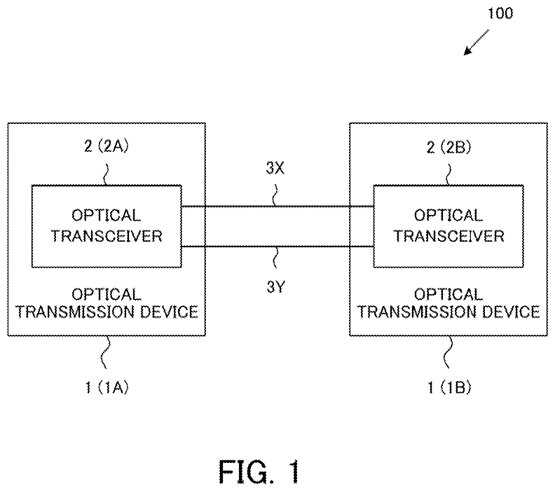

FIG. 1 illustrates an example of an optical transmission system in accordance with embodiments of the present invention. An optical transmission system 100 in accordance with embodiments of the present invention includes a plurality of optical transmission devices 1 (1A, 1B). Each optical transmission device includes an optical transceiver 2. In particular, the optical transmission device 1A includes an optical transceiver 2A, and the optical transmission device 1B includes an optical transceiver 2B. A pair of optical transmission lines 3X and 3Y are provided between the optical transmission devices 1A and 1B. An optical signal propagates from the optical transmission device 1A to the optical transmission device 1B through the optical transmission line 3X. An optical signal propagates from the optical transmission device 1B to the optical transmission device 1A through the optical transmission line 3Y. One or more optical nodes may be provided on each of the optical transmission lines 3X and 3Y.

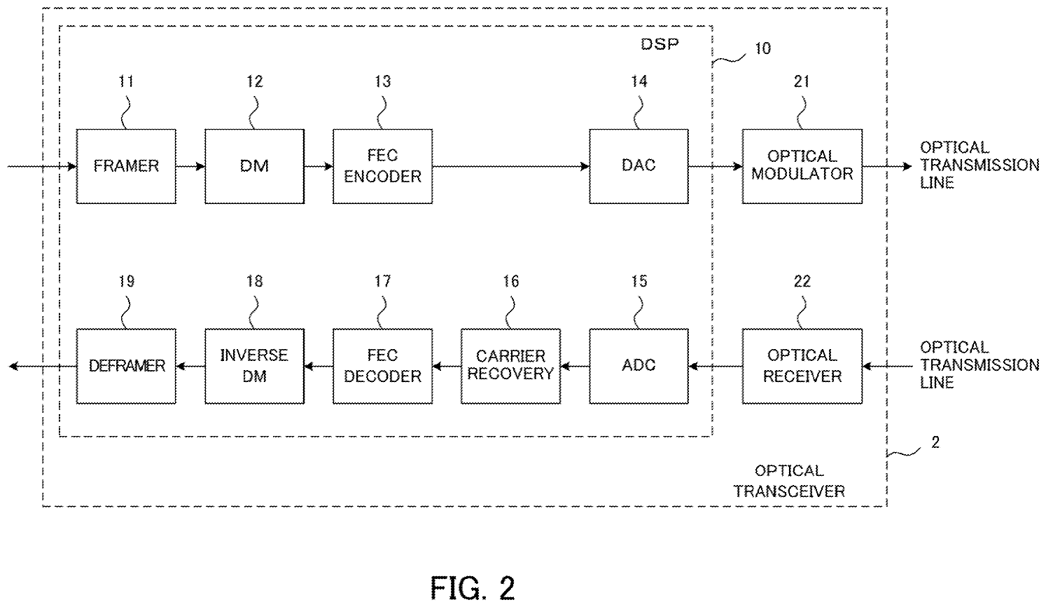

FIG. 2 illustrates an example of an optical transceiver in accordance with embodiments of the present invention. As described above by referring to FIG. 1, an optical transceiver 2 is implemented in each of the optical transmission devices 1. The optical transceiver 2 includes a framer 11, a DM processor 12, a FEC encoder 13, a D/A converter 14, an A/D converter 15, a carrier recovery 16, a FEC decoder 17, an Inverse DM processor 18, a deframer 19, an optical modulator 21, and an optical receiver 22. The optical transceiver 2 may include other circuits or functions that are not depicted in FIG. 2.

The framer 11 stores transmission data in a frame. For example, transmission data may be stored in an OTUCn frame. The DM processor 12 performs a DM process for some of information bits stored in the frame. The DM process, which will be described in detail hereinafter, is an example of bit conversion for probabilistic shaping. The FEC encoder 13 adds an error correction code to information bits. The D/A converter 14 converts an output signal of the FEC encoder 13 into an analog signal. The optical modulator 21 generates a modulated optical signal based on an output signal of the D/A converter 14. In particular, a modulated optical signal indicating information bits for which probabilistic shaping and error correction coding have been performed is generated. The modulated optical signal is transmitted to the correspondent node via the optical transmission line.

The optical receiver 22 generates an electric signal indicating an optical signal received from the correspondent node. This electric signal indicates an electric field (amplitude and phase) of the received optical signal. The A/D converter 15 converts an output signal of the optical receiver 22 into a digital signal. The carrier recovery 16 recovers a waveform in an output signal of the A/D converter 15. The FEC decoder 17 performs an error correction process for the received signal. Note that a decoding process performed by the FEC decoder 17 corresponds to an encoding process performed by a FEC encoder 13 implemented in the correspondent node. The Inverse DM processor 18 performs reverse conversion for bit conversion performed by a DM processor 12 implemented in the correspondent node. The deframer 19 extracts data stored in the frame and outputs the data.

In the optical transceiver 2, the framer 11, the DM processor 12, the FEC encoder 13, the D/A converter 14, the A/D converter 15, the carrier recovery 16, the FEC decoder 17, the Inverse DM processor 18, and the deframer 19 are implemented by, for example, a digital signal processor (DSP) 10. However, the framer 11, the DM processor 12, the FEC encoder 13, the carrier recovery 16, the FEC decoder 17, the Inverse DM processor 18, and the deframer 19 may be implemented by a combination of software and a hardware circuit.

In this example, the optical transceiver 2 transmits a 64 QAM modulated signal. In 64 QAM, symbols are transmitted using 64 signal points on a constellation. In 64 QAM, each symbol carries six bits.

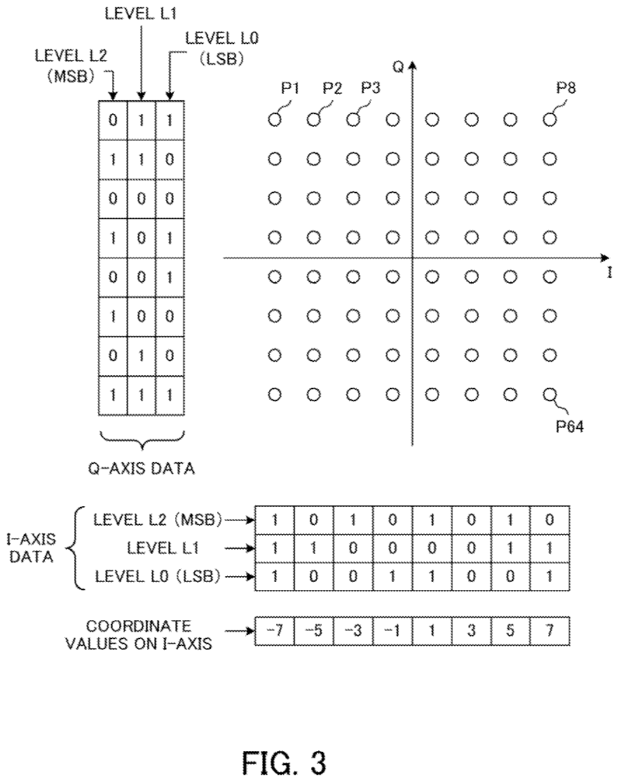

FIG. 3 illustrates an example of symbol mapping according to 64 QAM. In 64 QAM, symbols are transmitted using 64 signal points P1-P64 on a constellation. The constellation is represented by an in-phase (I) axis and a quadrature (Q) axis orthogonal to each other. In 64 QAM, six bits of data are allocated to each transmission symbol. The transmission symbol is mapped to a signal point corresponding to values of six bits. Specifically, each symbol is represented by three bits of I-axis data and three bits of Q-axis data. The transmission symbol is mapped to a signal point corresponding to a combination of three bits of I-axis data and three bits of Q-axis data. For example, when I-axis data is “111” and Q-axis data is “011,” a transmission symbol is allocated to the signal point P1. When I-axis data is “010” and Q-axis data is “011,” a transmission symbol is allocated to the signal point P2. The optical transceiver 2 transmits the symbol with an amplitude and a phase corresponding to the signal point.

The power of a transmission symbol is dependent on the distance between the center (or origin) of the constellation and a signal point. Specifically, the power of a transmission symbol allocated to a signal point close to the center of the constellation is low. By contrast, the power of a transmission symbol allocated to a signal point distant from the center of the constellation is high. Thus, the average transmission power is low when symbols have a high probability of being allocated to a signal point close to the center of the constellation.

Accordingly, the optical transceiver 2 performs probabilistic shaping to convert transmission data such that a signal point close to the center of the constellation is used with a high probability. The data conversion is performed by the DM processor 12.

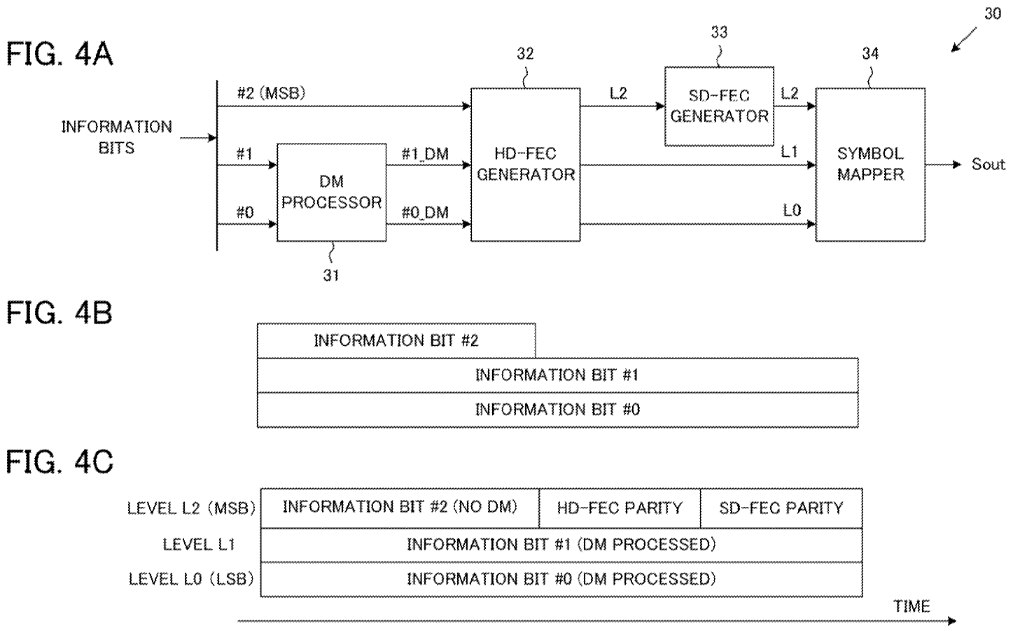

FIGS. 4A-4C illustrate an example of the configuration and operations of an encoder circuit in accordance with embodiments of the present invention. An encoder circuit 30 in accordance with embodiments of the present invention includes a DM processor 31, a HD-FEC generator 32, an SD-FEC generator 33, and a symbol mapper 34. The encoder circuit 30 is provided between the framer 11 and the D/A converter 14 depicted in FIG. 2. Thus, in this example, the encoder circuit 30 is implemented by the DSP 10. Meanwhile, the DM processor 31 corresponds to the DM processor 12 depicted in FIG. 2. The HD-FEC generator 32, the SD-FEC generator 33, and the symbol mapper 34 correspond to the FEC encoder 13 depicted in FIG. 2.

The encoder circuit 30 separately processes the I-axis data and the Q-axis data depicted in FIG. 3. Thus, the optical transceiver 2 may include two encoder circuits 30 illustrated in FIG. 4A. In this case, operations of the two encoder circuits 30 are substantially the same.

The encoder circuit 30 is supplied with information bits stored in a transmission frame. This frame is generated by the framer 11 depicted in FIG. 2. In this regard, a 64 QAM modulated signal is generated in this example. Thus, each symbol is represented by three bits of I-axis data and three bits of Q-axis data. Hence, the encoder circuit 30 is supplied with information bits #0-#2 depicted in FIG. 4B. Note that the information bit #2 is a most significant bit (MSB), and the information bit #0 is a least significant bit (LSB).

The DM processor (distribution matcher) 31 performs a DM process for bit strings other than an MSB bit string. Thus, the DM process is performed for the information bits #0 and #1. As a result, a DM-processed information bit #0 and a DM-processed information bit #1 are generated. As a general rule, the DM-processed information bit #0 and the DM-processed information bit #1 are longer than the information bit #0 before the DM process and the information bit #1 before the DM process. The length of the DM-processed information bit #0 may be the same as the length of the DM-processed bit #1. Note that the DM processor 31 is an example of a converter that converts information bits so as to implement probabilistic shaping. The DM process will be described hereinafter.

The HD-FEC generator 32 generates parity bits by performing an encoding process for the DM-processed information bits #0 and #1 and the information bit #2. In this example, the HD-FEC generator 32 uses an encoding method in which the receiver node performs soft decision decoding. For example, the HD-FEC generator 32 may use Bose-Chaudhuri-Hocquenghem (BCH) code, but the invention is not particularly limited to this. Parity bits generated by the HD-FEC generator 32 may hereinafter be referred to as a “HD-FEC parity.” As depicted in FIG. 4C, the HD-FEC parity is disposed in the MSB bit string.

The SD-FEC generator 33 encodes the MSB bit string. In particular, the SD-FEC generator 33 generates parity bits by performing an encoding process for the information bit #2 and the HD-FEC parity. In this example, the SD-FEC generator 33 uses an encoding method in which the receiver node performs soft decision decoding. For example, the SD-FEC generator 33 may use low-density parity-check (LDPC) code, but the invention is not particularly limited to this. Parity bits generated by the SD-FEC generator 33 may hereinafter be referred to as an “SD-FEC parity.” As depicted in FIG. 4C, the SD-FEC parity is also disposed in the MSB bit string. The total bit length of the information bit #2, the HD-FEC parity, and the SD-FEC parity is the same as the length of each of the DM-processed information bits #0 and #1.

In accordance with a mapping rule determined in advance, the symbol mapper 34 sequentially maps, for each symbol, data stored in the data frame depicted in FIG. 4C to a corresponding signal point. In this case, as described above by referring to FIG. 3, the symbol mapper 34 determines a signal point based on values of three bits. For example, a symbol having “111” as the values of levels L2-L0 of I-axis data is mapped to a signal point on the constellation that has a coordinate value of “−7” in an I-axis direction. A symbol having “010” as the values of levels L2-L0 of I-axis data is mapped to a signal point that has a coordinate value of “−5” in the I-axis direction.

The optical transceiver 2 includes an encoder circuit 30 that processes I-axis data and an encoder circuit 30 that processes Q-axis data. Thus, a corresponding one signal point is determined based on the values of levels L2-L0 of I-axis data and the values of levels L2-L0 of Q-axis data. The optical transceiver 2 transmits the one symbol (i.e., six bits of information) by using the determined signal point.

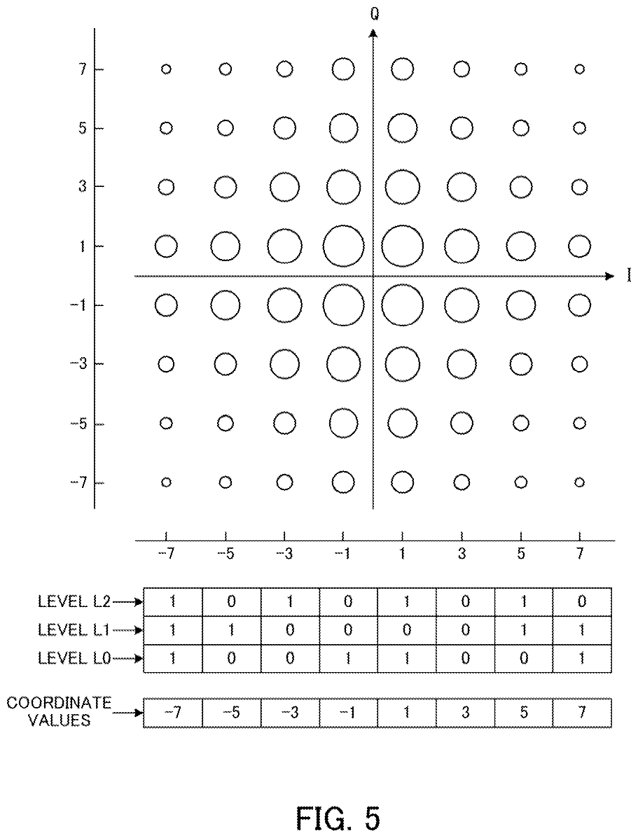

FIG. 5 is an explanatory diagram for an overview of probabilistic shaping. Note that 64 circles indicated in FIG. 5 represent signal points according to 64 QAM. The size of each circle represents a probability that a transmission symbol will be allocated. Specifically, a signal point corresponding to a large circle has a high probability of being allocated a symbol, and a signal point corresponding to a small circle has a low probability of being allocated a symbol.

Probabilistic shaping converts input information bits such that a signal point close to the center of the constellation is used with a high probability. In this example, probabilistic shaping is performed by the DM processor 31. However, the DM processor 31 performs the DM process for the information bits #0-#1, as described above by referring to FIGS. 4A-4C. That is, the DM processor 31 does not perform the DM process for the information bit #2.

In this example, the symbol mapper 34 maps transmission symbols to corresponding signal points according to the mapping pattern depicted in FIG. 5. Thus, a symbol having “01” as the values of lower two bits is mapped to a coordinate “1” or “−1” on the constellation. Likewise, a symbol having “00” as the values of lower two bits is mapped to a coordinate “3” or “−3,” a symbol having “10” as the values of lower two bits is mapped to a coordinate “5” or “−5,” and a symbol having “11” as the values of lower two bits is mapped to a coordinate “7” or “−7.”

The DM processor 31 converts information bits #0-#1 such that a signal point close to the center of the constellation is used with a high probability.

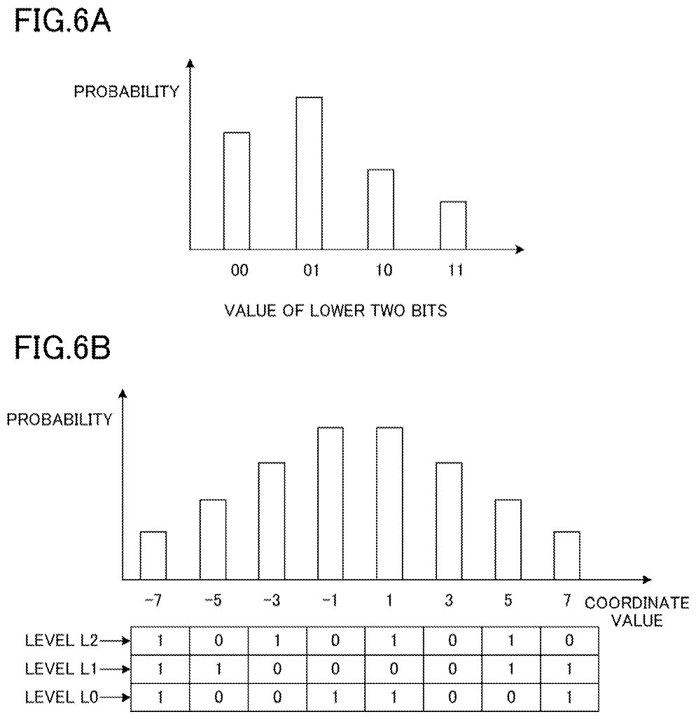

Specifically, as indicated in FIG. 6A, the DM processor 31 converts the information bits #0-#1 such that: symbols having “01” as the values of lower two bits have the highest probability of occurring; symbols having “00” as the values of lower two bits have the second highest probability of occurring; symbols having “10” as the values of lower two bits have the third highest probability of occurring; and symbols having “11” as the values of lower two bits have the lowest probability of occurring.

According to the mapping pattern used by the symbol mapper 34, each pair of adjacent signal points on the constellation are different from each other in terms of the value of MSB (level L2 in this example). Specifically, as indicated in FIG. 6B, symbols having “1” as the value of an MSB are mapped to signal points on the constellation that have a coordinate value of “−7,” “−3,” “1,” or “5.” Symbols having “0” as the value of an MSB are mapped to signal points on the constellation that have a coordinate value of “−5,” “−1,” “3,” or “7.” Accordingly, the closer to the center of the constellation, the higher the probability of occurrence is, and a symmetrical distribution is attained with respect to the center of the constellation.

As described above, the encoder circuit 30 performs the DM process for lower bits (information bits #0 and #1) and then generates a HD-FEC parity for DM-processed information bits #0-#1 and a most significant bit (information bit #2). The encoder circuit 30 also generates an SD-FEC parity for the most significant bit (information bit #2 and HD-FEC parity). In this way, the data frame depicted in FIG. 4C is provided. In addition, the encoder circuit 30 maps each symbol in the data frame to a corresponding signal point so as to generate a signal Sout. The optical transceiver 2 generates a modulated optical signal by modulating continuous wave light with the signal Sout.

According to this configuration, probabilistic shaping causes signal points close to the center of the constellation to be used with a high probability, thereby decreasing average transmission power for modulated optical signals. In other words, when modulated optical signals are transmitted with a specified average transmission power, the Euclidean distances between signal points on the constellation can be increased. Hence, the error rate can be improved.

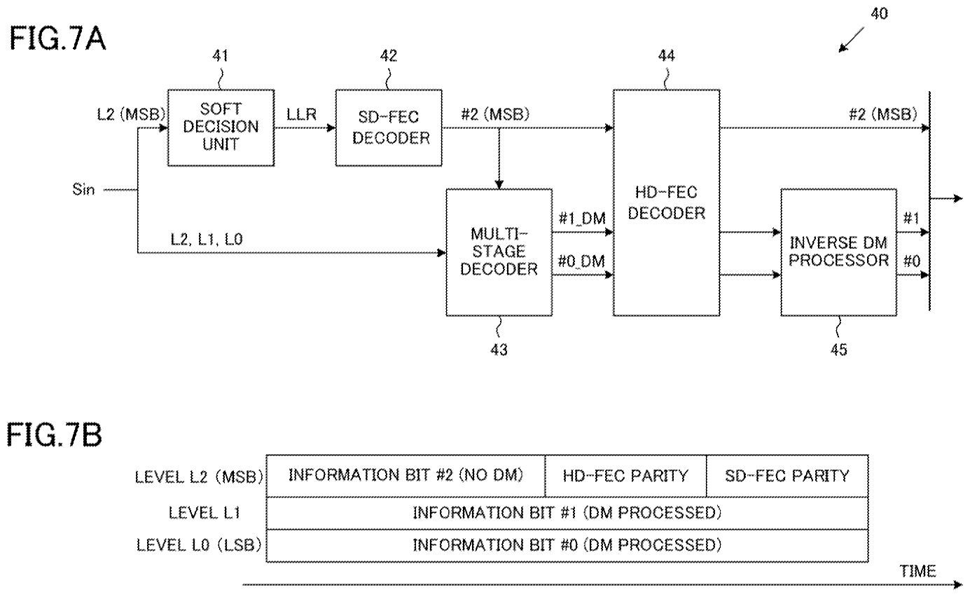

FIGS. 7A and 7B illustrate an example of the configuration and operations of a decoder circuit in accordance with embodiments of the present invention. A decoder circuit 40 in accordance with embodiments of the present invention includes a soft decision unit 41, an SD-FEC decoder 42, a multi-stage decoder 43, a HD-FEC decoder 44, and an Inverse DM processor 45. The decoder circuit 40 is provided between the A/D converter 15 and the deframer 19 depicted in FIG. 2. Thus, in this example, the decoder circuit 40 is implemented by the DSP 10. The soft decision unit 41, the SD-FEC decoder 42, the multi-stage decoder 43, and the HD-FEC decoder 44 correspond to the FEC decoder 17 depicted in FIG. 2, and the Inverse DM processor 45 corresponds to the Inverse DM processor 18 depicted in FIG. 2.

The decoder circuit 40 separately processes an I-component signal and a Q-component signal. Thus, the optical transceiver 2 may include two decoder circuits 40 indicated in FIG. 7A. In this case, operations of the two decoder circuits 40 are substantially the same.

The decoder circuit 40 is supplied with an electric signal indicating a received optical signal. In this example, the optical receiver 22 depicted in FIG. 2 generates an I-component signal indicating an I component of the received optical signal and a Q-component signal indicating a Q component of the received optical signal. The I-component signal indicates an I component on the constellation that the electric field of the received optical signal has. The Q-component signal indicates a Q component on the constellation that the electric field of the received optical signal has. The decoder circuit 40 is supplied with the I-component signal or the Q-component signal as a received signal Sin depicted in FIG. 7A.

The soft decision unit 41 calculates, for each received symbol, a log likelihood ratio (LLR) of an MSB based on the value of a received signal Sin. The LLR value indicates the logarithm of the ratio between the probability that the received signal was “1” at a transmitter and the probability that the received signal was “0” at the transmitter.

The SD-FEC decoder 42 determines the value of the MSB based on the LLR value calculated by the soft decision unit 41. In this way, the bit string of the level L2 depicted in FIG. 7B is recovered. In particular, the information bit #2, the HD-FEC parity, and the SD-FEC parity are recovered. In this case, the SD-FEC decoder 42 may perform belief propagation decoding. A belief propagation decoding algorithm includes iterative processing of updating the LLR value of each bit until a parity check using the SD-FEC parity satisfies a specified condition. Decision results obtained for the bits when the parity check is satisfied are output as decoding results.

The multi-stage decoder 43 demaps each received symbol based on electric field information (i.e., received signal Sin) indicating a received optical signal. In this case, the multi-stage decoder 43 converts each received symbol into three bits of data in accordance with a mapping rule determined in advance. Note that the mapping rule used by the multi-stage decoder 43 is the same as the mapping rule used by the symbol mapper 34 in the transmitter node.

However, the MSB of the three bits forming each symbol has been obtained by the SD-FEC decoder 42. Accordingly, the multi-stage decoder 43 demaps each received symbol by using the value of the MSB obtained by the SD-FEC decoder 42.

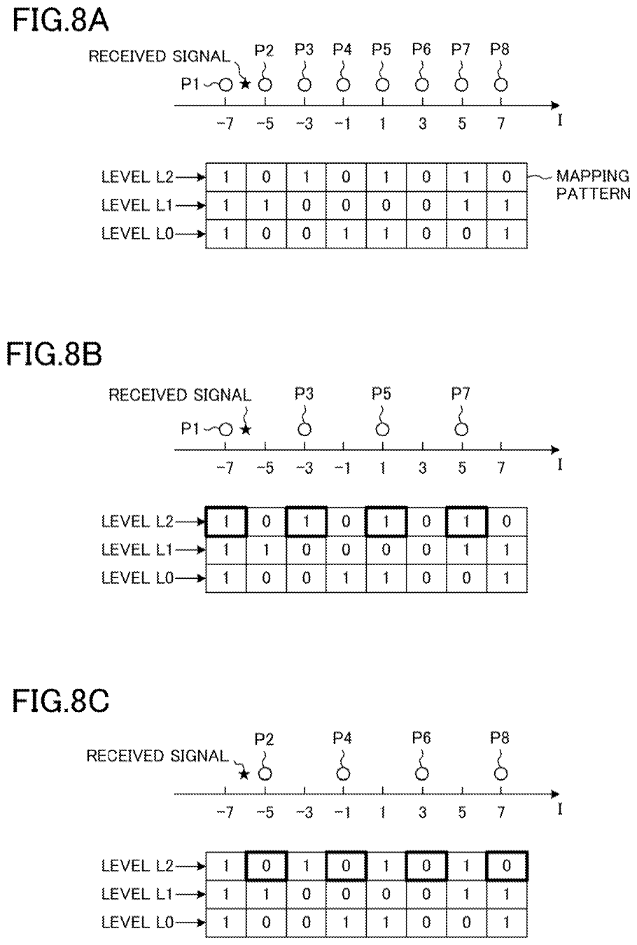

FIGS. 8A-8C illustrate an example of a decoding process performed by the multi-stage decoder 43. The following indicates an example in which I-axis data is decoded, but substantially the same method is used for decoding Q-axis data.

In this example, eight signal points P1-P8 are arranged along the I axis of the constellation, as depicted in FIG. 8A. Coordinate values of the signal points P1-P8 are “−7” to “7.” Here, it is assumed that the value of the I component of the electric field of a received signal detected by the optical receiver 22 is “−6.”

For example, the received signal may be decoded by detecting a signal point among the signal points P1-P8 that is the closest to the received signal. However, in the example depicted in FIG. 8A, the distance between the received signal and the signal point P1 and the distance between the received signal and the signal point P2 are nearly equal. In this case, the decoder cannot decide whether the signal point used by the transmitter node was P1 or P2. That is, the decoder cannot decide whether the data transmitted from the transmitter node is “111” or “010.” Hence, a bit error may occur.

The multi-stage decoder 43 demaps each received symbol by using the value of the MSB obtained by the SD-FEC decoder 42. For example, as indicated in FIG. 8B, when the value of the MSB is “1,” it is decided that the signal point used by the transmitter node was P1, P3, P5, or P7. Thus, the multi-stage decoder 43 detects a signal point among the signal points P1, P3, P5, and P7 that is the closest to the received signal. As a result, the signal point P1 is detected, and “111” is obtained as a decoding result. By contrast, as indicated in FIG. 8C, when the value of the MSB is “0,” it is decided that the signal point used by the transmitter node was P2, P4, P6, or P8. Thus, the multi-stage decoder 43 detects a signal point among the signal points P2, P4, P6, and P8 that is the closest to the received signal. As a result, the signal point P2 is detected, and “010” is obtained as a decoding result.

As described above, the number of candidates for a signal point corresponding to a received signal is reduced according to the value of an MSB obtained by the SD-FEC decoder 42. Hence, the error rate is improved by performing coding in multiple stages.

The HD-FEC decoder 44 performs error corrections for an MSB (level L2) obtained by the soft decision unit 41 and the SD-FEC decoder 42 and lower bits (levels L1 and L0) obtained by the multi-stage decoder 43. In this example, the information bit #2, the HD-FEC parity, and the SD-FEC parity are stored in level L2. The DM-processed information bits #1-#0 are stored in levels L1-L0. The HD-FEC decoder 44 performs error corrections for the information bit #2 and the DM-processed information bits #1-#0 by using the HD-FEC parity. The SD-FEC parity is not needed for the HD-FEC decoder 44.

The Inverse DM processor 45 performs an Inverse DM process for the DM-processed information bits #1-#0. In particular, the Inverse DM processor 45 performs reverse conversion corresponding to data conversion performed by the DM processor 31 implemented in the transmitter node. As a result, the bit string before the DM process performed by the transmitter node (i.e., information bits #1-#0) is recovered. Hence, the decoder circuit 40 acquires the information bits #2-#0.

### Effects of Embodiments of Present Invention

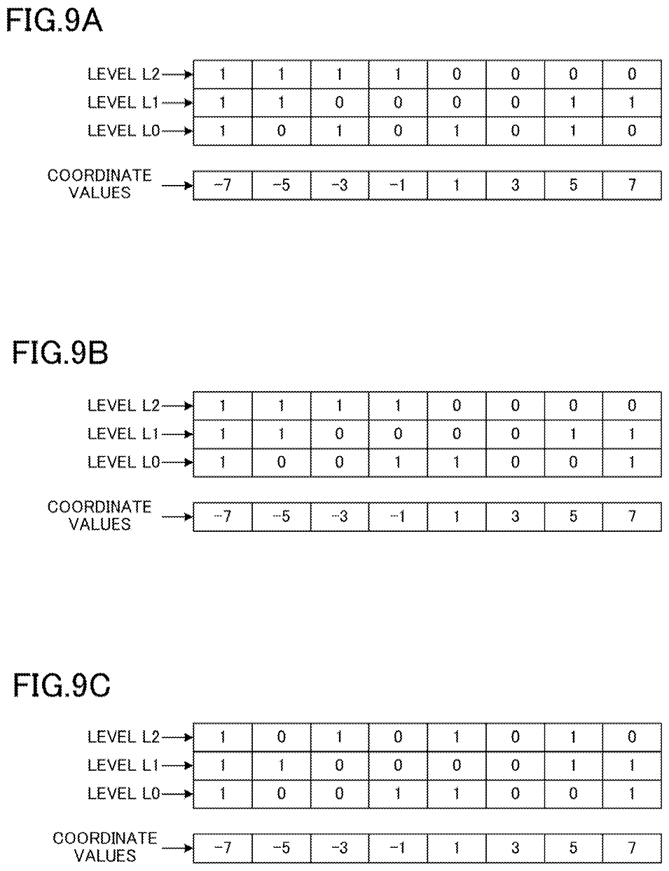

FIG. 9A-9C are explanatory diagrams for effects provided according to mapping patterns. FIGS. 9A and 9B depict mapping patterns for comparison with embodiments of the present invention. FIG. 9C depicts a mapping pattern in embodiments of the present invention.

The mapping pattern depicted in FIG. 9A is considered to be preferable for a transmission system that performs multilevel coding (MLC) without performing probabilistic shaping. According to this mapping pattern, each pair of adjacent signal points on the constellation are different from each other in terms of the value of LSB (level L0). Specifically, symbols having “1” as the value of LSB are mapped to signal points on the constellation that have a coordinate value of “−7,” “−3,” “1,” or “5,” and symbols having “0” as the value of LSB are mapped to signal points on the constellation that have a coordinate value of “−5,” “−1,” “3,” or “7.” Accordingly, it is considered that the effects described above by referring to FIGS. 8A-8C may be provided by, for example, using multilevel code for performing the soft decision for the LSB.

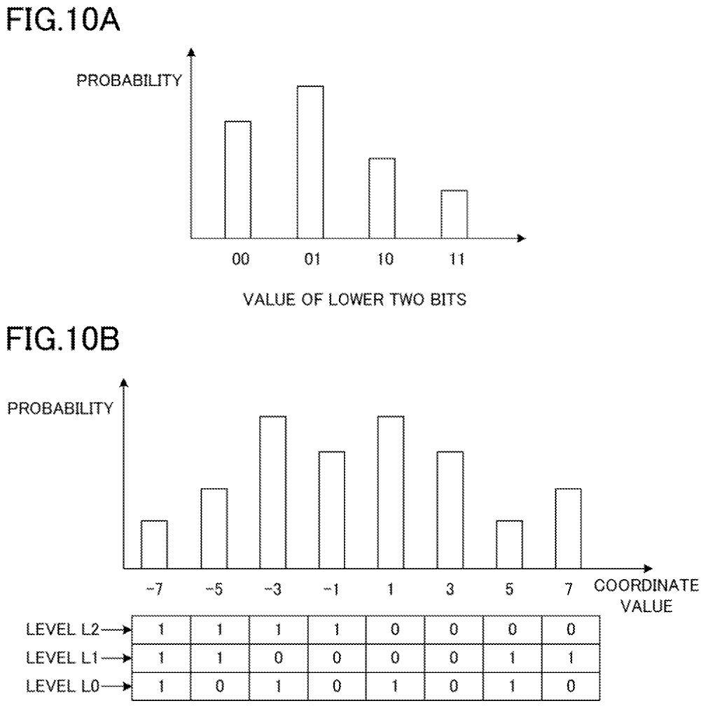

However, in the transmission system using this mapping pattern, performing probabilistic shaping may not attain a sufficiently high probability that signal points close to the center of the constellation will be used. Assume, for example, that data conversion is performed through the DM process such that the probabilities of occurrence of lower two bits attain a distribution depicted in FIG. 10A. In this case, as depicted in FIG. 10B, the probability of using signal points close to the center of the constellation is not sufficiently high.

By contrast, according to a mapping pattern in embodiments of the present invention, as depicted in FIG. 9C, the values of bits for which the DM process is performed (i.e., levels L1 and L0) are symmetrical with respect to the center of the constellation. Hence, the distribution depicted in FIG. 6B can be attained through the DM process. Thus, the probability of using signal points close to the center of the constellation is sufficiently high. Hence, the embodiments of the present invention allow for reduction of the average transmission power. In other words, in a case where signals are transmitted with a specified average transmission power, the Euclidean distances between signal points can be increased, thereby enhancing the noise tolerance of the transmission signals.

The mapping pattern depicted in FIG. 9B (Gray code mapping) can solve the problem of the mapping pattern depicted in FIG. 9A. In particular, the values of bits for which the DM process is performed (levels L1 and L0) are symmetrical with respect to the center of the constellation. Hence, the effect of probabilistic shaping can be sufficiently provided. However, this mapping pattern involves regions in which no change is made in the values of bits for which the DM process is not performed (i.e., level L2). Specifically, the values of level L2 are always “0” in a region in which coordinate values on the constellation are positive, and the values of level L2 are always “1” in a region in which coordinate values on the constellation are negative. Thus, the effect of multilevel coding described above by referring to FIGS. 8A-8C cannot be attained.

By contrast, according to a mapping pattern in embodiments of the present invention, as depicted in FIG. 9C, the values of bits for which the DM process is performed (levels L1 and L0) are symmetrical with respect to the center of the constellation, and each pair of adjacent signal points are different from each other in terms of the value of bit for which the DM process is not performed (i.e., level L2). In this example, the lower two bits of the mapping pattern depicted in FIG. 9C are the same as the lower two bits of the mapping pattern depicted in FIG. 9B, and the MSBs of the mapping pattern depicted in FIG. 9C are the same as the LSBs of the mapping pattern depicted in FIG. 9A. Specifically, symbols having “01” as the values of lower two bits are disposed at “−1” or “1” on the constellation, symbols having “00” as the values of lower two bits are disposed at “−3” or “3” on the constellation, symbols having “10” as the values of lower two bits are disposed at “−5” or “5” on the constellation, and symbols having “11” as the values of lower two bits are disposed at “−7” or “7” on the constellation. Symbols having “1” as the value of MSB are disposed at “−7,” “−3,” “1,” or “5” on the constellation, and symbols having “0” as the value of MSB are disposed at “−5,” “−1,” “3,” or “7” on the constellation.

As described above, the values of bits for which the DM process is performed (levels L1 and L0) are symmetrical with respect to the center of the constellation, so the average transmission power can be reduced by performing probabilistic shaping for these bits. Moreover, each pair of adjacent signal points are different from each other in terms of the value of bit for which the DM process is not performed (i.e., level L2), so bit errors in levels L1-L0 can be reduced by multilevel code for performing the process of multi-stage decoder using the value of bit in level L2. Accordingly, the embodiments of the present invention can provide both the effect of probabilistic shaping and the effect of multilevel codes.

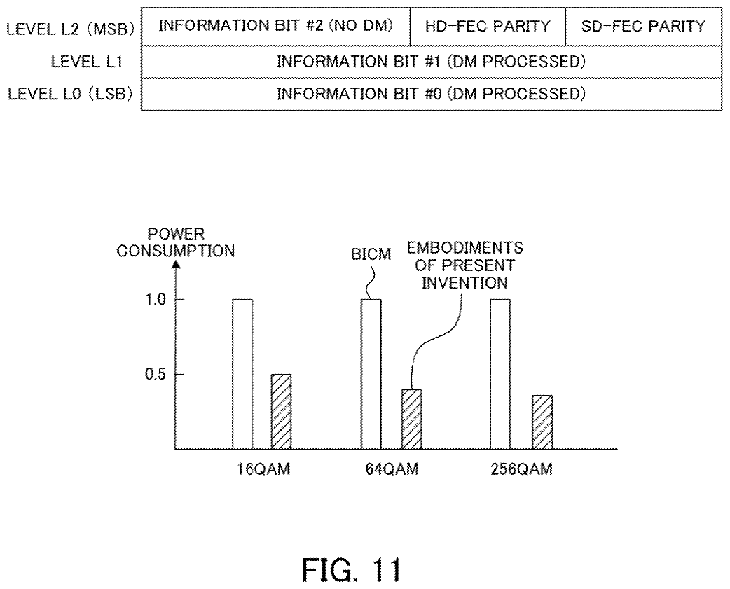

FIG. 11 is an explanatory diagram for reduction of power consumption. In the following, power consumption of the decoder circuit 40 of the receiver node will be studied. In the decoder circuit 40, power consumption caused by iterative processing for the soft decision is dominant.

In bit-interleaved coded modulation (BICM), which is a type of error correction code, a plurality of levels (L0-L2) forming a data frame are collectively encoded. Thus, even in the case of the data frame depicted in FIG. 11, SD-FEC parities will be generated for all the bit strings (DM-processed information bits #0-#1, information bit #2, and HD-FEC parity). The decoder circuit 40 performs the soft decision for all the bits. Hence, the soft decision is performed for much more bits, thereby increasing power consumption. Note that, in FIG. 11, the power consumption BICM is normalized as “1.”

By contrast, in embodiments of the present invention using multilevel code, SD-FEC parities are generated only for bits for which probabilistic shaping is not performed (i.e., MSBs). Specifically, SD-FEC parities are generated for information bits #2 and HD-FEC parities. The decoder circuit 40 performs the soft decision for only MSBs. Hence, the soft decision is performed for a decreased number of bits, thereby reducing power consumption in comparison with BICM, as indicated in FIG. 11.

In the examples described above, the encoder circuit 30 stores parities in a most significant bit string, and the most significant bit string is first decoded in multistage decoding by the decoder circuit 40. However, the present invention is not limited to this procedure. In particular, the encoder circuit 30 may store a parity in any bit string (hereinafter, “first bit string”) among three bit strings forming the data frame. However, in this case, the DM process (i.e., probabilistic shaping) is performed for the information bits stored in the bit strings other than the first bit string. Meanwhile, the decoder circuit 40, in multistage decoding, first decodes the first bit string, and decodes the other bit strings by using the result of decoding the first bit string.

The encoder circuit 30 may process I-axis data and Q-axis data by using one digital signal processor, or may process each of I-axis data and Q-axis data by using a corresponding digital signal processor. Likewise, the decoder circuit 40 may process I-axis data and Q-axis data by using one digital signal processor, or may process each of I-axis data and Q-axis data by using a corresponding digital signal processor.

### 256 QAM

In the examples depicted in FIGS. 3-10B, data is transmitted with 64 QAM. However, the present invention is not limited to this. In particular, the present invention can be applied to a transmission system that uses 2^{2N}-QAM (N is an integer larger than 1).

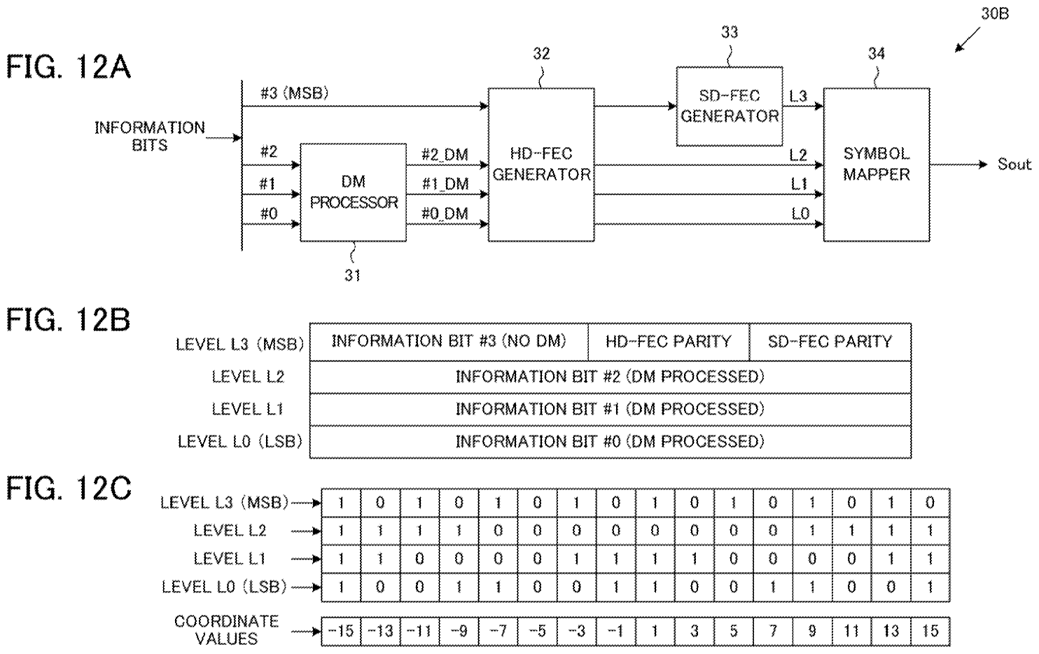

FIGS. 12A-12C illustrate an example of the configuration and operations of an encoder circuit applied to 256 QAM. An encoder circuit 30B applied to 256 QAM has substantially the same configuration as the encoder circuit 30 depicted in FIG. 4A.

However, the encoder circuit 30B processes four bit strings (L3-L0), as depicted in FIG. 12A. A DM processor 31 performs probabilistic shaping for the lower three bits, not including the MSB. That is, DM-processed information bits #0-#2 are generated from information bits #0-#2. A HD-FEC generator 32 generates a HD-FEC parity from the DM-processed information bits #0-#2 and the information bit #3. The SD-FEC generator 33 generates an SD-FEC parity from the MSB bit string (i.e., the information bit #3 and the HD-FEC parity). As depicted in FIG. 12B, the HD-FEC parity and the SD-FEC parity are stored in the MSB bit string (i.e., level L3).

According to a mapping pattern indicated in FIG. 12C, a symbol mapper 34 maps each symbol to a corresponding signal point based on values of four bits. According to this mapping pattern, the values of bits for which the DM process is performed (levels L2-L0) are also symmetrical with respect to the center of the constellation, and each pair of adjacent signal points are also different from each other in terms of the value of bit for which the DM process is not performed (i.e., level L3). Accordingly, both the effect of probabilistic shaping and the effect of multilevel codes can be provided.

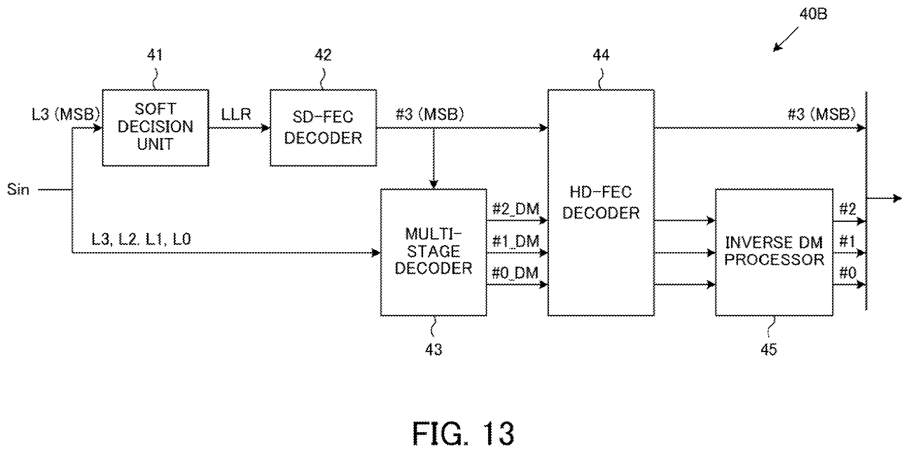

FIG. 13 illustrates an example of the configuration and operations of a decoder circuit applied to 256 QAM. A decoder circuit 40B applied to 256 QAM has substantially the same configuration as the decoder circuit 40 depicted in FIG. 7A.

However, in the decoder circuit 40B, a soft decision unit 41 and an SD-FEC decoder 42 decode an MSB (L3), and a multi-stage decoder 43 demaps lower bits (L2-L0) by using the value of the MSB obtained by the SD-FEC decoder 42. An Inverse DM processor 45 recovers information bits #0-#2 by performing the Inverse DM process for the levels L2-L0.

### Variation of 16 QAM

The encoder circuit and the decoder circuit in accordance with embodiments of the present invention can also be applied to 16 QAM. The encoder circuit and the decoder circuit applied to 16 QAM may have the configurations depicted in FIGS. 4A and 7A, respectively. However, the encoder circuit and the decoder circuit applied to 16 QAM may perform the process without separating I-axis data and Q-axis data.

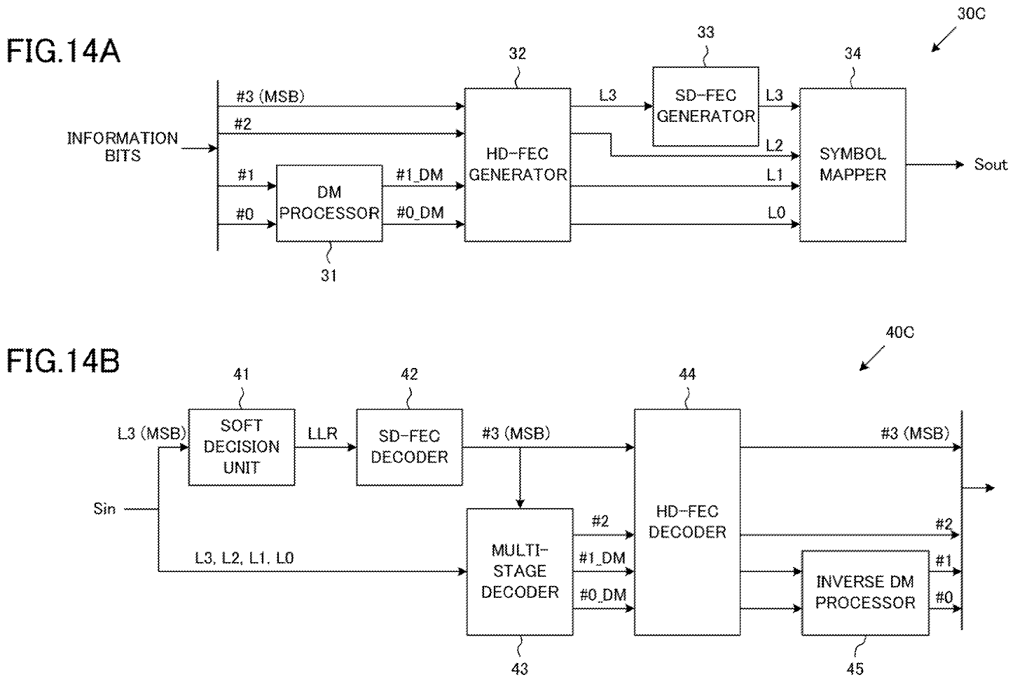

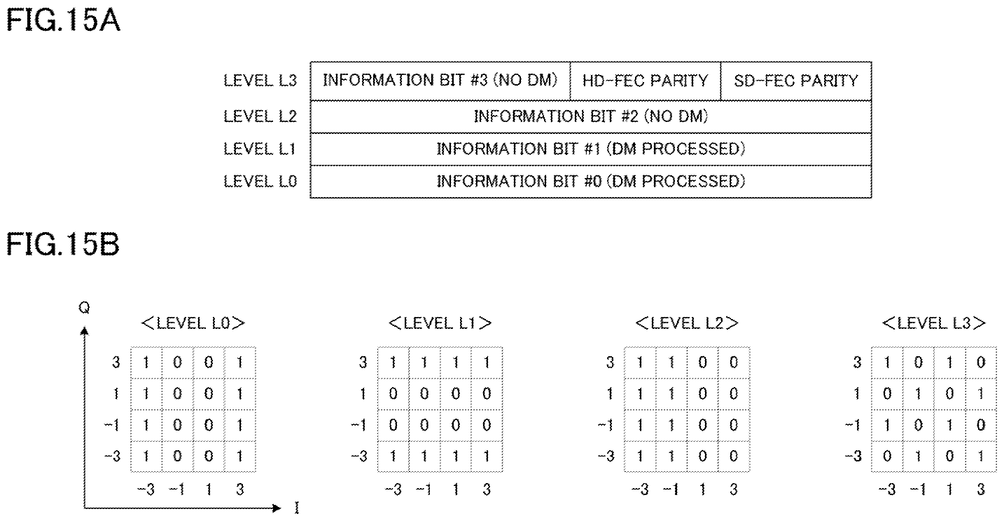

FIGS. 14A and 14B illustrate variations of the encoder circuit and the decoder circuit applied to 16 QAM. As depicted in FIG. 14A, an encoder circuit 30C includes a DM processor 31, a HD-FEC generator 32, an SD-FEC generator 33, and a symbol mapper 34. The encoder circuit 30C generates a data frame depicted in FIG. 15A. In addition, the encoder circuit 30C maps transmission symbols to corresponding signal points according to a mapping pattern depicted in FIG. 15B.

The DM processor 31 converts information bits #0-#1 such that a signal point close to the center of the constellation is used with a high probability. In a case where the mapping pattern depicted in FIG. 15B is used, the information bits #0-#1 are converted such that: the probability of occurrence of a symbol having “00” as the values of levels L1-L0 is the highest; and the probability of occurrence of a symbol having “11” as the values of levels L1-L0 is the lowest. Note that the DM process is not performed for the levels L3-L2.

The HD-FEC generator 32 performs coding for the levels L3-L0. In particular, a HD-FEC parity is generated for DM-processed information bits #0-#1 and information bits #2-#3. The HD-FEC parity is stored at the level L3. The SD-FEC generator 33 performs coding only for the level L3. That is, an SD-FEC parity is generated for the information bit #3 and the HD-FEC parity. The SD-FEC parity is also stored at the level L3. The symbol mapper 34 maps transmission symbols to corresponding signal points according to the mapping pattern depicted in FIG. 15B.

As depicted in FIG. 14B, a decoder circuit 40C includes a soft decision unit 41, an SD-FEC decoder 42, a multi-stage decoder 43, a HD-FEC decoder 44, and an Inverse DM processor 45. The soft decision unit 41 and the SD-FEC decoder 42 recover an MSB (i.e., level L3) from a received signal. Thus, the information bit #3 and the HD-FEC parity are acquired. The multi-stage decoder 43 recovers the lower bits (i.e., levels L2-L0) by using the value of the MSB obtained by the SD-FEC decoder 42. In this way, the DM-processed information bits #0-#1 and the information bit #2 are acquired. The HD-FEC decoder 44 performs an error correction by using the HD-FEC parity. The Inverse DM processor 45 recovers the information bits #1-#0 by performing the Inverse DM process for the levels L1-L0.

As depicted in FIG. 15B, the values of bits for which probabilistic shaping is performed (levels L1-L0) are symmetrical with respect to the center of the constellation in each of an I-axis direction and a Q-axis direction. Meanwhile, each pair of signal points adjacent to each other in each of the I-axis direction and the Q-axis direction are different from each other in terms of the value of bit (level L3) decoded first by the multi-stage decoder 43. Accordingly, this configuration can also provide both the effect of probabilistic shaping and the effect of multilevel codes.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present inventions have been described in detail, it should be understood that the various changes, substitutions, and alterations could be made hereto without departing from the spirit and scope of the invention.

What is claimed is:

1. An encoder circuit that encodes information bits in a transmission system that transmits symbols by using 2^{2N} signal points on a constellation, N being an integer larger than 2, the encoder circuit comprising:
a symbol mapper configured to allocate each symbol of a data frame including information bits, a first code and a second code to a corresponding signal point among the 2^{2N} signal points according to a mapping pattern;
a converter configured to convert information bits stored in other bit strings among N bit strings forming the data frame excluding a first bit string among the N bit strings, such that a probability that each symbol is allocated to a signal point close to a center of the constellation is high;
a first encoder configured to generate the first code from information bits stored in the first bit string and the information bits converted by the converter; and
a second encoder configured to generate the second code from the information bits stored in the first bit string and the first code; wherein
the first code and the second code are stored in the first bit string,
the mapping pattern indicates a correspondence between a signal point and values of N bits corresponding to the N bit strings,
in the mapping pattern, values of bits corresponding to the other bit strings are arranged symmetrically with respect to the center of the constellation, and
in the mapping pattern, each pair of adjacent signal points on the constellation are different from each other in terms of a value of bit corresponding to the first bit string.

2. The encoder circuit according to claim 1, wherein
the first bit string is initially decoded by multistage decoding performed by a decoder circuit configured to decode a signal generated by the encoder circuit.

3. A decoder circuit that decodes a signal generated by an encoder circuit in a transmission system that transmits symbols by using 2^{2N} signal points on a constellation, N being an integer larger than 2, wherein
the encoder circuit includes
a symbol mapper configured to allocate each symbol of a data frame including information bits, a first code and a second code to a corresponding signal point among the 2^{2N} signal points according to a mapping pattern,
a converter configured to convert information bits stored in other bit strings among N bit strings forming the data frame excluding a first bit string among the N bit strings, such that a probability that each symbol is allocated to a signal point close to a center of the constellation is high,
a first encoder configured to generate the first code from information bits stored in the first bit string and the information bits converted by the converter, and
a second encoder configured to generate the second code from the information bits stored in the first bit string and the first code,
the first code and the second code are stored in the first bit string,
the mapping pattern indicates a correspondence between a signal point and values of N bits corresponding to the N bit strings,
in the mapping pattern, values of bits corresponding to the other bit strings are arranged symmetrically with respect to the center of the constellation,
in the mapping pattern, each pair of adjacent signal points on the constellation are different from each other in terms of a value of bit corresponding to the first bit string,
the decoder circuit comprises:
a first decoder configured to recover each bit of the first bit string by using a soft decision;
a second decoder configured to recover each bit of the other bit strings by using each bit of the first bit string recovered by the first decoder; and
a reverse converter configured to perform, for the other bit strings recovered by the second decoder, reverse conversion corresponding to the conversion performed by the converter.

4. The decoder circuit according to claim 3, wherein
the first decoder performs an error correction for the first bit string by using the second code, the second code being obtained by recovering each bit of the first bit string.

5. The decoder circuit according to claim 3, wherein
the second decoder performs an error correction for the information bits stored in the data frame by using the first code, the first code being obtained by recovering each bit of the first bit string.

6. An encoding method for encoding information bits in a transmission system that transmits symbols by using 2^{2N} signal points on a constellation, N being an integer larger than 2, the encoding method comprising:
converting information bits stored in other bit strings among N bit strings forming a data frame storing information bits, such that a probability that each symbol is allocated to a signal point close to a center of the constellation is high, the other bit strings excluding a first bit string among the N bit strings;
generating a first code from information bits stored in the first bit string and the converted information bits; and
generating the second code from the information bits stored in the first bit string and the first code, wherein
the first code and the second code are stored in the first bit string,
each symbol of the data frame is allocated to a corresponding signal point among the 2^{2N} signal points according to a mapping pattern indicating a correspondence between a signal point and values of N bits corresponding to the N bit strings,
in the mapping pattern, values of bits corresponding to the other bit strings are arranged symmetrically with respect to the center of the constellation, and
in the mapping pattern, each pair of adjacent signal points on the constellation are different from each other in terms of a value of bit corresponding to the first bit string.

7. A decoding method for decoding a signal generated by an encoder circuit in a transmission system that transmits symbols by using 2^{2N} signal points on a constellation, N being an integer larger than 2, wherein
the encoder circuit includes
a symbol mapper configured to allocate each symbol of a data frame including information bits, a first code and a second code to a corresponding signal point among the 2^{2N} signal points according to a mapping pattern,
a converter configured to convert information bits stored in other bit strings among N bit strings forming the data frame excluding a first bit string among the N bit strings, such that a probability that each symbol is allocated to a signal point close to a center of the constellation is high,
a first encoder configured to generate the first code from information bits stored in the first bit string and the information bits converted by the converter, and
a second encoder configured to generate the second code from the information bits stored in the first bit string and the first code,
the first code and the second code are stored in the first bit string,
the mapping pattern indicates a correspondence between a signal point and values of N bits corresponding to the N bit strings,
in the mapping pattern, values of bits corresponding to the other bit strings are arranged symmetrically with respect to the center of the constellation,
in the mapping pattern, each pair of adjacent signal points on the constellation are different from each other in terms of a value of bit corresponding to the first bit string, and
the decoding method comprises:
recovering each bit of the first bit string by using a soft decision;
recovering each bit of the other bit strings by using each bit of the recovered first bit string; and
performing, for the recovered other bit strings, reverse conversion corresponding to the conversion performed by the converter.

8. An encoder circuit that encodes information bits in a transmission system that transmits symbols by using 16 signal points on a constellation, the 16 signal points corresponding to 16 QAM, the encoder circuit comprising:
a symbol mapper configured to allocate each symbol of a data frame including information bits, a first code and a second code to a corresponding signal point among the 16 signal points according to a mapping pattern;
a converter configured to convert information bits stored in a first bit string and a second bit string among four bit strings forming the data frame, such that a probability that each symbol is allocated to a signal point close to a center of the constellation is high;
a first encoder configured to generate the first code from the information bits converted by the converter and information bits stored in a third bit string and a fourth bit string among the four bit strings; and
a second encoder configured to generate the second code from the information bits stored in the fourth bit string and the first code, wherein
the first code and the second code are stored in the fourth bit string,
the mapping pattern indicates a correspondence between a signal point and values of four bits corresponding to the four bit strings,
in the mapping pattern, values of bits corresponding to the first bit string and the second bit string are arranged symmetrically with respect to the center of the constellation in each of two coordinate-axis directions of the constellation, and
in the mapping pattern, each pair of adjacent signal points on the constellation are different from each other, in each of the two coordinate-axis directions of the constellation, in terms of a value of bit corresponding to the fourth bit string.
